(19) United States
(12) Patent Application Publication
(10) Pub. No.: US 2021/0107279 A1
(43) Pub. Date: Apr. 15, 2021

(54) ZONAL ACTUATOR FAULT DETECTION

(71) Applicant: Hewlett-Packard Development Company, L.P., Spring, TX (US)

(72) Inventors: Daryl E. Anderson, Corvallis, OR (US); Eric Martin, Corvallis, OR (US); James Michael Gardner, Corvallis, OR (US)

(73) Assignee: Hewlett-Packard Development Company, L.P., Spring, TX (US)

(21) Appl. No.: 16/956,045

(22) PCT Filed: Mar. 5, 2018
(86) PCT No.: PCT/US2018/020876

§ 371 Date: Jun. 19, 2020

(51) Int. Cl. B41J 2/045; G01R 17/02

(52) U.S. Cl. CPC B41J 2/04581; G01R 17/02; B41J 2/04555; B41J 2/0451

(57) ABSTRACT

In one example in accordance with the present disclosure, a fluidic die is described is described. The fluidic die includes an array of fluid actuators grouped into zones. Each zone includes a number of fluid actuators and at least one fault detection device. The fault detection device includes a comparator to compare at least one of a representation of a supply voltage and a return voltage supplied to the zone against a voltage threshold. The fault detection device also includes a fault capture device to store an output of the comparator.

### BACKGROUND

A fluidic die is a component of a fluidic system. The fluidic die includes components that manipulate fluid flowing through the system. For example, a fluidic ejection die, which is an example of a fluidic die, includes a number of nozzles that eject fluid onto a surface. The fluidic die also includes non-ejecting actuators such as micro-recirculation pumps that move fluid through the fluidic die. Through these nozzles and pumps, fluid, such as ink and fusing agent among others, is ejected or moved.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a block diagram of a fluidic die for zonal actuator evaluation, according to an example of the principles described herein.

FIG. 2 is a block diagram of a fluidic die for zonal actuator evaluation, according to an example of the principles described herein.

FIG. 3 is a flow chart of a method for zonal actuator evaluation, according to an example of the principles described herein.

FIG. 4 is a circuit diagram of a fluidic die for zonal actuator evaluation, according to an example of the principles described herein.

FIG. 5 is a circuit diagram of a fluidic die for zonal actuator evaluation, according to another example of the principles described herein.

FIG. 6 is a flow chart of a method for zonal actuator evaluation, according to an example of the principles described herein.

FIGS. 7A and 7B are diagrams indicating a predetermined window during which actuator evaluation occurs, according to an example of the principles described herein.

FIG. 8 is a circuit diagram of a first comparator and a second comparator, according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

Fluidic dies, as used herein, may describe a variety of types of integrated devices with which small volumes of fluid may be pumped, mixed, analyzed, ejected, etc. Such fluidic dies may include ejection dies, such as those found in printers, additive manufacturing distributor components, digital titration components, and/or other such devices with which volumes of fluid may be selectively and controllably ejected.

In a specific example, these fluidic systems are found in any number of printing devices such as inkjet printers, multi-function printers (MFPs), and additive manufacturing apparatuses. The fluidic systems in these devices are used for precisely, and rapidly, dispensing small quantities of fluid. For example, in an additive manufacturing apparatus, the fluid ejection system dispenses fusing agent. The fusing agent is deposited on a build material, which fusing agent facilitates the hardening of build material to form a three-dimensional product.

Other fluid systems dispense ink on a two-dimensional print medium such as paper. For example, during inkjet printing, fluid is directed to a fluid ejection die. Depending on the content to be printed, the device in which the fluid ejection system is disposed determines the time and position at which the ink drops are to be released/ejected onto the print medium. In this way, the fluid ejection die releases multiple ink drops over a predefined area to produce a representation of the image content to be printed. Besides paper, other forms of print media may also be used.

Accordingly, as has been described, the systems and methods described herein may be implemented in a two-dimensional printing, i.e., depositing fluid on a substrate, and in three-dimensional printing, i.e., depositing a fusing agent or other functional agent on a material base to form a three-dimensional printed product.

Each fluidic die includes a fluid actuator to eject/move fluid. In a fluidic ejection die, a fluid actuator may be disposed in an ejection chamber, which chamber has an opening. The fluid actuator in this case may be referred to as an ejector that, upon actuation, causes ejection of a fluid drop via the opening.

Fluid actuators may also be pumps. For example, some fluidic dies include microfluidic channels. A microfluidic channel is a channel of sufficiently small size (e.g., of nanometer sized scale, micrometer sized scale, millimeter sized scale, etc.) to facilitate conveyance of small volumes of fluid (e.g., picoliter scale, nanoliter scale, microliter scale, milliliter scale, etc.). Fluidic actuators may be disposed within these channels which, upon activation, may generate fluid displacement in the microfluidic channel.

Examples of fluid actuators include a piezoelectric membrane based actuator, a thermal resistor based actuator, an electrostatic membrane actuator, a mechanical/impact driven membrane actuator, a magneto-strictive drive actuator, or other such elements that may cause displacement of fluid responsive to electrical actuation. A fluidic die may include a plurality of fluid actuators, which may be referred to as an array of fluid actuators.

While such fluidic systems and dies undoubtedly have advanced the field of precise fluid delivery, some conditions impact their effectiveness. For example, the power delivery regime of a fluidic die may not be able to keep up with other technological changes to the fluidic die. For example, as fluidic dies shrink in size to meet consumer demand or as more circuit elements are added between the power source and the array of fluid actuators, power delivery becomes more difficult as there are fewer thin film layers through which power can be delivered and more components that act as a source of parasitic loss. Each of these circumstances may have a deleterious effect on fluidic performance.

For example, the energy a fluid actuator uses to effectuate fluid manipulation is related to the voltage difference across it. Accordingly, a drop in electrical power may affect the fluid actuator's ability to perform an operation such as fluidic ejection or fluidic movement. As a specific numeric example, an actuator array may be optimized to operate when coupled to a 32 V supply signal and a ground signal. However, due to parasitic losses, which may be more prevalent with reduced size components, the supply voltage that is actually seen by an actuator in the array may be 28 V and the power return node at that same actuator may be 3V instead of 0 on ground, due to parasitic rise. Consequently, instead of 32 V across the fluid actuator, there would be 25 V across the fluid actuator. This reduced voltage may result in an actuation of the fluid actuator that is not full strength and thus affects ejection/movement of the fluid, or may not result in any ejection/movement at all. Such losses may be more prevalent at those positions along the array furthest from a power supply or a return, for example, a middle region of a column array.

Accordingly, the present specification is directed to a fluidic die that includes multiple arrays of fluid actuators, each of the arrays being divided into zones of fluid actuators. Components within each zone monitor power delivery to fluid actuators in that zone. If a supply voltage level drops below a threshold value or if a return voltage level rises above a threshold value, a fault signal is sent to global circuitry that informs the printer. The printer could then make any variety of adjustments including adjusting print masks, power settings, or other parameters to bring the power delivery to each zone back to a desired level. Specifically, a controller could increase the supply voltage, reduce the number of nozzles that are fired at the same time, slow down the print speed so that the amount of fluid per area remains the same as before, and increase a pulse width of power delivered to the fluid actuators. As such, a device in which the fluidic die is included, can optimize printing based on actual power delivery to the fluidic die and that is specific to that fluidic die.

Specifically, the present specification describes a fluidic die. The fluidic die includes an array of fluid actuators grouped into zones. Each zone includes a number of fluid actuators and at least one fault detection device. The fault detection device includes 1) a comparator to compare at least one of a representation of a supply voltage and a return voltage supplied to the zone against a voltage threshold and 2) a fault capture device to store an output of the comparator.

The present specification also describes a fluidic die that includes the array of fluid actuators grouped into zones, each zone having a number of fluid actuators. In this example, the fluidic die includes a first fault detection device and a second fault detection device. The first fault detection device includes 1) a first comparator to compare a representation of a supply voltage against a supply voltage threshold and 2) a first fault capture device to store the output of the first comparator. The second fault detection device includes 1) a second comparator to compare a return voltage against a return voltage threshold and 2) a second fault capture device to store the output of the second comparator. The fluidic die includes detection chain logic to combine outputs of each fault capture device such that the contents of all fault capture devices in the array are conveyed in a collective fashion to a controller.

The present specification also describes a method. According to the method, during an evaluation mode 1) a representation of a supply voltage supplied to a zone of fluid actuators is compared against a supply voltage threshold and 2) a return voltage from the zone of fluid actuators is compared against a return voltage threshold. A fault is determined to have occurred in the zone when either 1) the supply voltage is less than the supply voltage threshold or 2) the return voltage is greater than the return voltage threshold. In either case, a signal indicative of a fault in any of the zones is then propagated to a controller of the fluidic die.

In one example, using such a fluidic die 1) allows for immediate detection of power faults at a zone level; 2) reports such faults such that remedial action may be taken; 3) allows for a controller to adjust print masks, power distribution, or other parameters, on the fly to optimize for the actual power delivery limitations of the system; and 4) may leverage circuitry used for other zonal sensing systems such as drive bubble detection systems.

As used in the present specification and in the appended claims, the term “actuator” refers to an ejecting actuator and/or a non-ejecting actuator. For example, an ejecting actuator operates to eject fluid from the fluid ejection die. A recirculation pump, which is an example of a non-ejecting actuator, moves fluid through the fluid slots, channels, and pathways within the fluidic die.

Accordingly, as used in the present specification and in the appended claims, the term “nozzle” refers to an individual component of a fluid ejection die that dispenses fluid onto a surface. The nozzle includes at least an ejection chamber, an ejector actuator, and an opening.

Further, as used in the present specification and in the appended claims, the term “fluidic die” refers to a component of a fluid ejection system that includes a number of fluid actuators. A fluidic die includes fluidic ejection dies and non-ejecting fluidic dies.

Still further, as used in the present specification and in the appended claims, the term “array” refers to a grouping of fluid actuators. A fluidic die may include multiple “arrays.” For example, a fluidic die may include multiple columns, each column forming an array.

Even further, as used in the present specification and in the appended claims, the term “zone” refers to a sub-division of an array. For example, a column of fluid actuators may include multiple zones.

Even further, as used in the present specification and in the appended claims, the term “fault capture device,” refers to an electrical component that can store a signal, such as a logic value. Examples of capture devices include flip-flops such as a set-reset flop, a D flip-flop, and others.

Yet further, as used in the present specification and in the appended claims, the term “fault-indicating output” refers to an output of a comparator that indicates a particular fault. For example, a comparator may generate an output indicating that the supply voltage seen at a zone of fluid actuators is less than a threshold amount, which is indicative of a fault. The comparator may then generate an output indicating this fault.

Even further, as used in the present specification and in the appended claims, the term “fault detection device” refers to hardware components within a zone to determine a fault within that zone. There may be multiple fault detection devices within a zone. For example a first fault detection device may detect and store a supply fault and a second fault detection device may detect and store a return fault.

Finally, as used in the present specification and in the appended claims, the term “a number of” or similar language is meant to be understood broadly as any positive number including 1 to infinity.

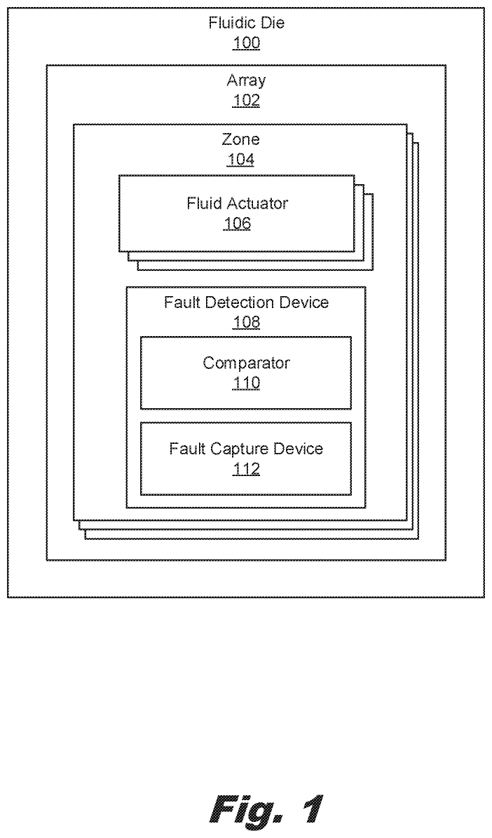

Turning now to the figures, FIG. 1 is a block diagram of a fluidic die (100) for zonal actuator evaluation, according to an example of the principles described herein. As described above, the fluidic die (100) is a part of a fluidic system that houses components for ejecting fluid and/or transporting fluid along various pathways. In some examples, the fluidic die (100) is a microfluidic die (100). That is, the channels, slots, and reservoirs on the microfluidic die (100) may be on a micrometer, or smaller, scale to facilitate conveyance of small volumes of fluid (e.g., picoliter scale, nanoliter scale, microliter scale, milliliter scale, etc.). The fluid that is ejected and moved throughout the fluidic die (100) can be of various types including ink, biochemical agents, and/or fusing agents. The fluid is moved and/or ejected via an array (102) of fluid actuators (106). Any number of fluid actuators (106) may be formed on the fluidic die (100). The fluidic die (100) may include any number of arrays (102). For example, the different arrays (102) on a fluidic die (100) may be organized as columns. In other examples, the array (102) may take different forms such as an N×N grid of fluid actuators (106).

Each array (102) is divided into different zones (104), a zone (104) referring to a sub-grouping of the fluid actuators (106) within a particular array (102). For example, in one column, i.e., array (102), of fluid actuators (106), multiple zones (104) of eight fluid actuators (106) may be present.

The fluidic die (100) includes a number of fluid chambers to hold a volume of the fluid to be move or ejected. The fluid chamber may take many forms. A specific example of such a fluid chamber is an ejection chamber where fluid is held prior to ejection from the fluidic die (100). In another example, the fluid chamber (100) may be a channel, or conduit through which the fluid travels. In yet another example, the fluid chamber (100) may be a reservoir where a fluid is held.

The fluid chambers (100) formed in the fluidic die (100) include fluid actuators (106) disposed therein, which fluid actuators (106) work to eject fluid from, or move fluid throughout, the fluidic die (100). The fluid chambers and fluid actuators (106) may be of varying types. For example, the fluid chamber may be an ejection chamber wherein fluid is expelled from the fluidic die (100) onto a surface for example such as paper or a 3D build bed. In this example, the fluid actuator (106) may be an ejector that ejects fluid through an opening of the fluid chamber.

In another example, the fluid chamber is a channel through which fluid flows. That is, the fluidic die (100) may include an array of microfluidic channels. Each microfluidic channel includes a fluid actuator (106) that is a fluid pump. In this example, the fluid pump, when activated, displaces fluid within the microfluidic channel. While the present specification may make reference to particular types of fluid actuators (106), the fluidic die (100) may include any number and type of fluid actuators (106).

These fluid actuators (106) may rely on various mechanisms to eject/move fluid. For example, an ejector may be a firing resistor. The firing resistor heats up in response to an applied voltage. As the firing resistor heats up, a portion of the fluid in an ejection chamber vaporizes to generate a bubble. This bubble pushes fluid out an opening of the fluid chamber and onto a print medium. As the vaporized fluid bubble collapses, fluid is drawn into the ejection chamber from a passage that connects the fluid chamber to a fluid feed slot in the fluidic die (100), and the process repeats. In this example, the fluidic die (100) may be a thermal inkjet (TIJ) fluidic die (100).

In another example, the fluid actuator (106) may be a piezoelectric device. As a voltage is applied, the piezoelectric device changes shape which generates a pressure pulse in the fluid chamber that pushes the fluid through the chamber. In this example, the fluidic die (100) may be a piezoelectric inkjet (PIJ) fluidic die (100).

As described above, such fluid actuators (106) rely on energy to actuate. The energy seen by fluid actuators (106) is based on a voltage potential across the fluid actuator (106). Accordingly, each zone (104) is coupled to a supply and a return. If 1) the supply voltage seen by a zone (104) is less than a predetermined threshold, 2) the return voltage from the zone (104) is greater than a predetermined threshold, or 3) combinations thereof, the voltage potential across the zone (104) may be less than sufficient to facilitate fluid actuation. Accordingly, the fluid actuators (106) in that zone (104) may underperform, or may not perform at all. Accordingly, each zone (104) includes fault detection devices (108) that detect either kind of fault, i.e., a fault in the supply side or a fault in the return side.

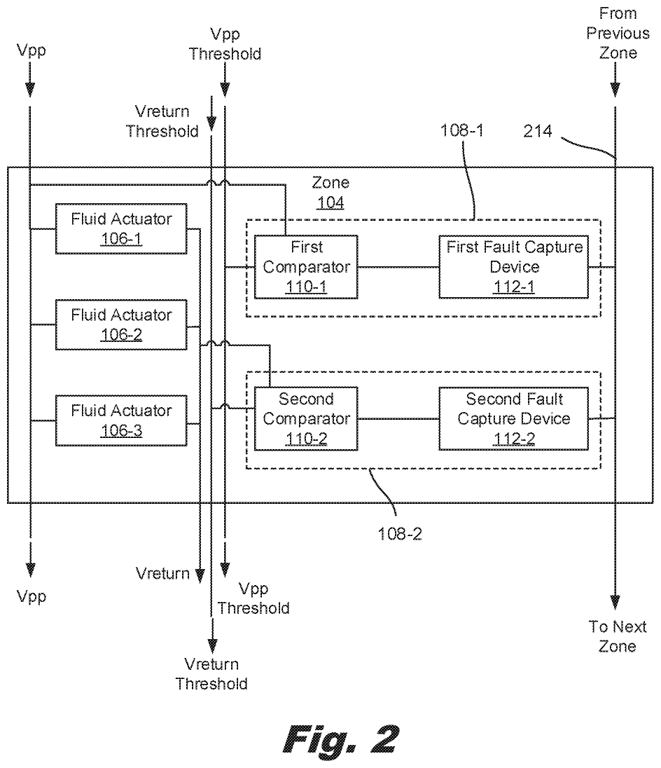

Specifically, a fault detection device (108) determines a fault on a supply side or a return side and includes a comparator (110) and a fault capture device (112). For example, the comparator (110) may compare a representation of a supply voltage supplied to the zone (104) against a supply voltage threshold or may compare a return voltage supplied to the zone (104) against a return voltage threshold. In some examples as depicted in FIG. 2, additional fault detection devices (108) can be added such that one determines a supply side fault and the other determines a return side fault.

In another example, additional fault detection devices (108) can be added to analyze different values of voltage differentials. For example, a fluidic die (100) may be supplied with a high voltage, i.e., 32 V, and a low voltage, i.e., 5 V, each with their own returns. In this example, the multiple fault detection devices (108) may analyze the returns corresponding to each supply. Each zone (104), based on its position within the array (102) and based on the fluidic die (100) position, among other fluidic die on a printing system, may see a different supply voltage due to different sources of loss along the path between the source and the zone (104).

Accordingly, as a specific example, the comparator (110) receives as input, a representation of the supply voltage at this zone (104) and also a supply voltage threshold, which threshold is a cutoff for sending an indication of a supply fault to a controller of the fluidic die (100). For example, if the array (102) is supplied with a supply voltage of 32 V, the supply voltage threshold may be set at 28 V. In this example, the comparator (110) compares the supply voltage seen at the zone (104), which may be less than 32 V, against the supply voltage threshold of 28 V. If the supply voltage drops below the threshold value, a fault-indicating output is passed to the fault capture device (112). Similarly, if the supply voltage seen at the zone (104) does not drop below the threshold value, a non-fault indicating output is passed to the fault capture device (112).

In another example, the fault detection device (108) determines a fault by analyzing a return side of the voltage differential. In this example, the comparator (110) compares a return voltage from the zone (104) against a return voltage threshold. That is, the comparator (110) receives as input, the return voltage leaving this zone (104) and also a return voltage threshold, which threshold is a cutoff for sending an indication of a return fault to a controller of the fluidic die (100). For example, if the array (102) is grounded to 0 V, the return voltage threshold may be set at 3 V. In this example, the comparator (110) compares the return voltage seen at the zone (104), which may be greater than 0 V due to parasitic losses on the return supply line, and compares it against the return voltage threshold of 3 V. If the return voltage rises above the threshold value, a fault indicating output is passed to the capture device (112). Similarly, if the return voltage seen at the zone (104) does not rise above the threshold value, a non-fault indicating output is passed to the capture device (112).

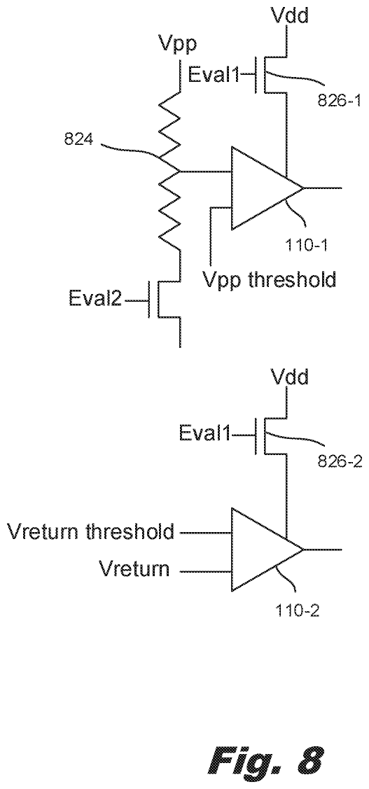

In other words, the fault detection device (108) outputs a signal indicating a fault based on a fault-indicating output of the comparator (110) or that the corresponding zone (104) is in a non-fault state. In this case, the fault-indicating output indicates either 1) that the supply voltage at the zone (104) is less than the supply voltage threshold or 2) that the return voltage at the zone (104) is greater than the return voltage threshold. In one example, the representation of the supply voltage may be the supply voltage, unaltered. In another example, the supply voltage may be scaled, or reduced. An example of a reduced representation of the supply voltage is provided in connection with FIG. 8.

Note that in this example, the fault detection device (108) can determine a fault either based on a supply voltage or a return voltage within the zone (104). Making such a determination based on just one side of the voltage differential is beneficial in that it reduces the circuitry on a fluidic die (100). Moreover, as the voltage differential between supply and threshold and return and threshold are mirrors, an overall drop in voltage differential based on the supply voltage and return voltage can be determined.

The fault capture device (112) is a component of the fault detection device (108) that receives the output of the comparator (110). The fault capture device (112) in some examples may be coupled to logic on the fluidic die (100) that aggregates data stored in other fault capture devices (112) such that an output of a detection chain indicates whether a fault is present on any of the zones (104) within the array (102).

Such a fluidic die (100) accounts for drops of power by providing an indication when power levels along the fluidic die (100) are insufficient to effectuate proper fluid actuation. For example, when, due to any number of circumstances, a particular zone (104) does not have sufficient voltage potential between its supply and return terminals to actuate fluid as configured, the fault detection device (108) is triggered and an output passed to a controller of the fluidic die (100) such that a remedial action, such as adjusting the print mask, power distribution, print speed, or firing parameters can be carried out.

FIG. 2 is a block diagram of a fluidic die (FIG. 1, 100) for zonal actuator evaluation, according to an example of the principles described herein. Specifically, FIG. 2 depicts a zone (104) of an array (FIG. 1, 102). As noted above, a fluidic die (FIG. 1, 100) may include any number of arrays (FIG. 1,102), which arrays (FIG. 1, 102) may be configured in any number of ways, including in columns.

Moreover, as described above, each zone (104) includes a number of fluid actuators (106). For simplicity, in FIG. 2, three fluid actuators (106) are depicted in a zone (104), but a zone (104) may include any number of fluid actuators (106). An energy potential is applied across the fluid actuators (106) in a zone (104) by coupling each zone (104) of fluid actuators (106) to a supply voltage, Vpp, and a return voltage, Vreturn. Each of the supply voltage, Vpp, and the return voltage, Vreturn, are coupled to each zone (104) in the array (FIG. 1, 102). That is, Vpp and Vreturn are global to zones (104) of the array (FIG. 1, 102). However, the voltages of Vpp and Vreturn at each zone (104) may be different due to different levels of parasitic loss along the path. The voltage differential between these two values Vpp and Vreturn at a particular zone (104) indicate whether or not the fluid actuators (106) in that zone (104) are receiving sufficient power to operate as expected. Accordingly, the fault detection devices (108) are implemented to measure such a voltage difference and determine whether or not a fault, i.e., an insufficient voltage difference, exists in that zone (104).

As described above, in some examples, the fluidic die (FIG. 1, 100) includes a first comparator (110-1) and a first fault capture device (112-1) to analyze at least one of a supply voltage and a return voltage against a respective threshold. In some examples, the fluidic die (FIG. 1, 100) includes additional comparators (110) and capture devices (112) as depicted in FIG. 2.

Accordingly, in a first fault detection device (108-1), the supply voltage, Vpp, and a supply voltage threshold, Vpp threshold, are passed to a first comparator (110-1). Note that the same voltage supply threshold, Vpp threshold, is passed to each zone (104) in an array (FIG. 1, 102) of fluid actuators (106). The first comparator (110-1) compares these two voltages and generates an output that is passed to the first fault capture device (112-1). Similarly, in a second fault detection device (108-2), the return voltage, Vreturn, and a return voltage threshold, Vreturn threshold, are passed to a second comparator (110-2). Note that the same return voltage threshold, Vreturn threshold, is passed to each zone (104) in an array (FIG. 1, 102) of fluid actuators (106). The second comparator (110-2) compares these two voltages and generates an output that is passed to the second fault capture device (112-2).

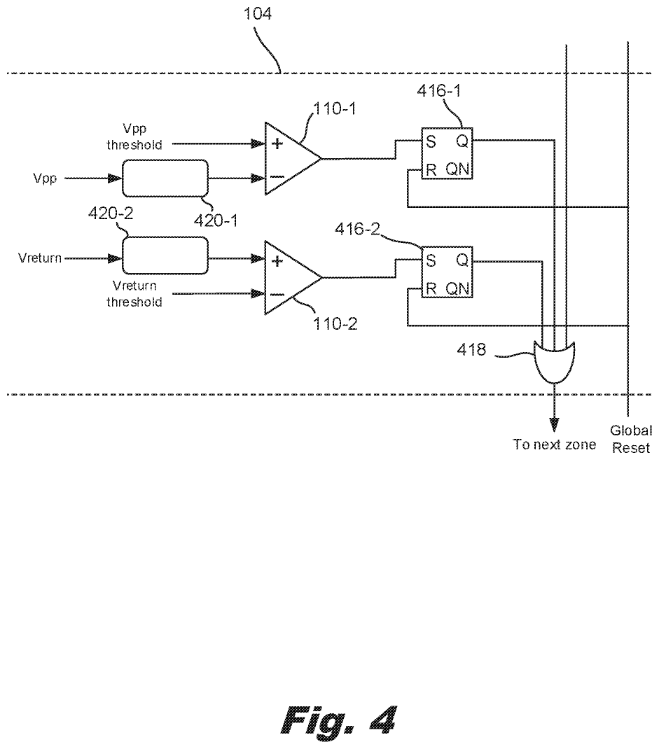

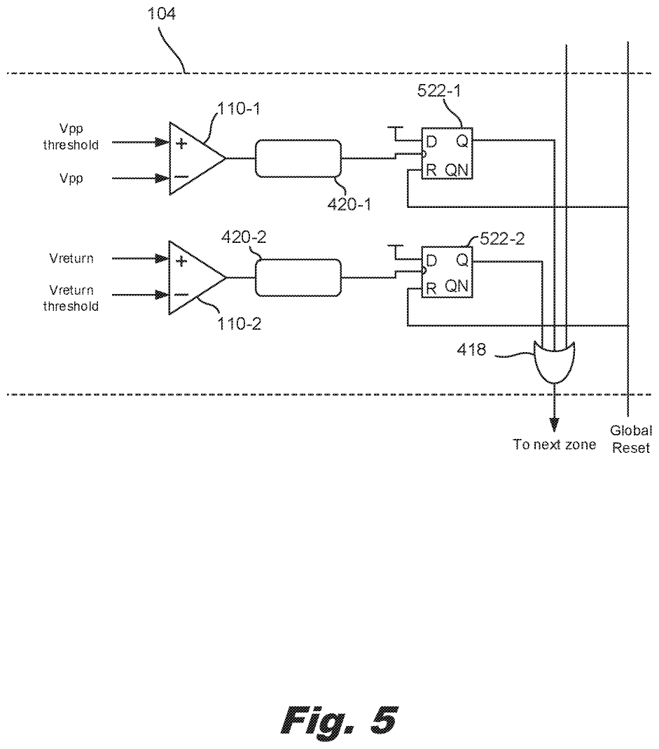

The fluidic die (100) also includes a detection chain (214) that has an output that indicates a fault in any of the zones (104) on the fluidic die (FIG. 1, 100). For example, an output of a previous zone (104) is passed to the present zone (104) where it is aggregated and passed to a subsequent zone (104). This operation repeats such that an output of the detection chain (214) is a value, which may be a single bit, indicative of a failure somewhere on the array (FIG. 1, 102). An example of circuitry forming the detection chain (214) is provided below in FIGS. 4 and 5.

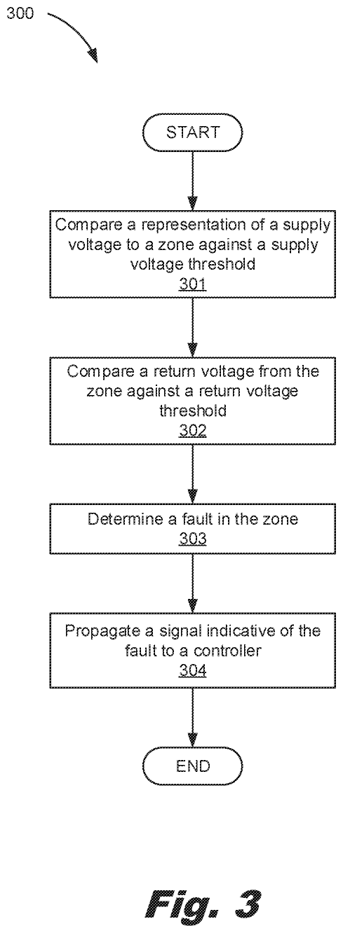

FIG. 3 is a flow chart of a method (300) for zonal actuator evaluation, according to an example of the principles described herein. The method (300) describes operations that occur during an evaluation period. That is, it may be determined that evaluation of the power delivery scheme of a fluidic die (FIG. 1, 100) is to be tested. During this evaluation period, a representation of a supply voltage, Vpp, supplied to a particular zone (FIG. 1, 104) is compared (block 301) against a supply voltage threshold, Vpp threshold. As described above, this may occur at the first comparator (FIG. 1, 110-1) of the zone (FIG. 1, 104). The supply voltage threshold, Vpp threshold, may be any value less than the supply voltage, Vpp, where it is deemed that sub-threshold voltages would result in less than a desired level of performance by the fluid actuators (FIG. 1, 106) in that zone (FIG. 1, 104). Note also that the supply voltages, Vpp, may differ at different zones (FIG. 1, 104). Accordingly, by comparing the supply voltage threshold, Vpp threshold, with the specific supply voltage, Vpp, seen at a zone (FIG. 1, 104), a localized result based on the actual operation of a particular fluid system can be determined.

As noted the representation of the supply voltage, Vpp, may include the actual supply voltage itself or a scaled version. The scaled version may be desirable for example, when the first comparator (FIG. 1, 110-1) is a low-voltage comparator, for consistency with the second comparator (FIG. 1, 110-2) which may be a low-voltage comparator. In this example, a high voltage source may damage the low-voltage first comparator (FIG. 1, 110-1).

Still during this evaluation period, the return voltage, Vreturn, from a particular zone (FIG. 1, 104) is compared (block 302) against a return voltage threshold, Vreturn threshold. As described above, this may occur at the second comparator (FIG. 1, 110-2) of the zone (FIG. 1, 104). The return voltage threshold, Vreturn threshold, may be any value greater than the return voltage, Vreturn, where it is deemed that supra-threshold voltages would result in a less than desired level of performance by the fluid actuators (FIG. 1, 106) in that zone (FIG. 1, 104). Note also that the return voltages may vary between zones (FIG. 1, 104). Accordingly, by comparing the return voltage threshold, Vreturn threshold, with the specific return voltage, Vreturn, seen at a zone (FIG. 1, 104), a localized result based on the actual operation of a particular fluid system can be determined.

With these comparisons (block 301, 302) made, the system can determine (block 303) a fault in the zone (FIG. 1, 104). Specifically, a fault is determined (block 303) when either 1) the supply voltage, Vpp, at the zone (FIG. 1, 104) is less than the supply voltage threshold, Vpp threshold or 2) the return voltage, Vreturn, at the zone (FIG. 1, 104) is greater than the return voltage threshold, Vreturn threshold. For example, given a supply voltage threshold of 32 V and a return voltage threshold of 3 V, a fault may be determined when the supply voltage, Vpp, at the zone (FIG. 1, 104) falls below 32 V or the return voltage, Vreturn, at the zone (FIG. 1, 104) is greater than 3 V. When either of these cases exists, it is indicative that a voltage potential across the zone (FIG. 1, 104) is insufficient to allow fluid actuator (FIG. 1, 106) operation as intended.

A signal indicative of a fault in any of the zones (FIG. 1, 104) is then propagated (block 304) to a controller. That is, a logical detection chain (FIG. 2, 214) includes logical elements in each zone (FIG. 1, 104) coupled to their respective fault capture devices (FIG. 1, 112). In one example, outputs of each fault capture device (FIG. 1, 112) are logically combined into a single aggregate signal such that an output indicates a fault somewhere within the array (FIG. 1, 102). Accordingly, the method (300) as described herein describes detection of a fault on the fluidic die (FIG. 1, 100) based on the specific operating parameters, i.e., Vpp and Vreturn, for that particular zone (FIG. 1, 104).

FIG. 4 is a circuit diagram of a fluidic die (FIG. 1, 100) for zonal actuator evaluation, according to an example of the principles described herein. Specifically, FIG. 4 is a circuit diagram of a zone (104). That includes a first comparator (110-1) for monitoring the supply voltage, Vpp, and a second comparator (110-2) for monitoring the return voltage, Vreturn, which return voltage is the supply that returns current from the fluidic actuators (FIG. 1, 106) back to the power supply device. In some examples, the return voltage is referred to as ground. Such comparators (110-1, 110-2) may be always active and therefore may, in some examples, monitor the power conditions continuously. However, in some examples, a comparison regulator may enable these comparators (110-1, 110-2) during a predetermined window to 1) save power and 2) protect against false indications of fault. Also as described above, each fault detection device (FIG. 1, 108) includes a fault capture device (FIG. 1, 112). In the example depicted in FIG. 4, the fault capture devices (FIG. 1, 112) are S-R flops (416-1, 416-2).

An example of the operation of this example is now provided. Prior to any fault detection, an output of each comparator (110-1, 110-2) may indicate expected operation, in this example represented by logic “0.” This value is passed to the “S” terminal of the S-R flops (416-1, 416-2) and set on the output terminal “Q.” As described above, each fault detection device (FIG. 1, 108) is coupled to detection chain (FIG. 2, 214) logic that aggregates the output of this zone (104) with that of other zones (104). In this example, that logic may implement an OR gate (418). The OR gate (418) outputs a signal indicating a fault when 1) the first S-R flop (416-1) indicates a fault, 2) the second S-R flop (416-2) indicates a fault, or 3) any upstream zone indicates a fault, wherein a fault is indicated with a logic “1.” If no fault is indicated on any input of the OR gate (418) an output of “0” passes to the next zone (104) and the process repeats.

In this example, the first comparator (110-1) has its “+” terminal connected to the supply threshold voltage, Vpp threshold, which is provided globally to all zones (104). The“−” terminal of the first comparator (110-1) is connected to the representation of the supply voltage, Vpp. Note that in some examples, each fault detection device (FIG. 1, 108) includes a low pass filter (420-1, 420-2). In the example depicted in FIG. 4, the low pass filters (420-1, 420-2) are disposed on an input of a respective comparator (110-1, 110-2) on which a supply voltage or return voltage is received. However, as depicted in FIG. 5, in some examples the low pass filters (420-1, 420-2) may be disposed on an output of a respective comparator (110-1, 110-2). In other examples, the comparators (110-1, 110-2) themselves may perform a filtering function. The low pass filters (420) filter out noise that may be found along the path of the supply and return voltages. Such noise may cause false triggers. Accordingly, the low pass filters (420) prevent such false fault triggers.

During operation, the first comparator (110-1) maintains a “0” logic, indicating expected operation, i.e., that the supply voltage, Vpp, at the zone (104) is greater than or equal to the supply voltage threshold, Vpp threshold. In the event that the supply voltage, Vpp, falls below the threshold, Vpp threshold, the output of the first comparator (110-1) will transition from a “O” to a “1” causing the S-R flop (416-1) to be set to a “1” and output that “1” along the “Q” terminal to be processed at the OR gate (418). This “1” indicating a supply fault will be communicated to the global die logic, and possibly to the printer, via a communication signal line that combines the fault signals from the S-R flops (416) of each zone (104). This “1” will remain on the first S-R flop (416-1) until the first S-R flop (416-1) is reset. That is, each fault detection device (FIG. 1, 108) includes a reset device, in this example the “R” terminal and the global reset line, to reset the respective fault capture device (FIG. 1, 112), in this example, the S-R flops (416-1, 416-2) after the fault has been acknowledged by a controller.

In this example, the second comparator (110-2) has its “−” terminal connected to the return threshold voltage, Vreturn threshold, which is provided globally to all zones (104). The “+” terminal of the second comparator (110-2) is connected to the return voltage, Vreturn, which may first pass through a low pass filter (420-2).

During operation, the second comparator (110-2) maintains a “0” logic, indicating expected operation, i.e., that the return voltage, Vreturn, from the zone (104) is less than or equal to the return voltage threshold, Vreturn threshold. In the event that the return voltage, Vreturn, rises above the threshold, Vreturn threshold, the output of the second comparator (110-2) will transition from a “0” to a “1” causing the second S-R flop (416-2) to be set to a “1” and output that “1” along the “Q” terminal to be processed at the OR gate (418). This “1” indicating a return fault will be communicated to the global die logic, and possibly to the printer, via a communication signal line that combines the fault signals from the S-R flops (416) of each zone (104). This “1” will remain on the second S-R flop (416-2) until the second S-R flop (416-2) is reset.

FIG. 5 is a circuit diagram of a fluidic die for zonal actuator evaluation, according to another example of the principles described herein. As described above, each fault detection device (FIG. 1, 108) includes a fault capture device (FIG. 1, 112). In the example depicted in FIG. 4, the fault capture devices (FIG. 1, 112) are D-flops (522-1, 522-2).

An example of the operation of this example is now provided. Prior to any fault detection, an output of each comparator (110-1, 110-2) may indicate expected operation, in this example represented by logic “0.” This output of the comparator (110) is coupled to the clock signal of the D-flops (522-1, 522-2). Note that in this example, the low pass filters (420-1, 420-2) are coupled to the output of the comparators (110-1, 110-2), but having the same effect of filtering out noise and preventing false indications of fault.

As described above, each fault detection device (FIG. 1, 108) is coupled to detection chain (FIG. 2, 214) logic that aggregates the output of this zone (104) with that of other zones (104). In this example, that logic may implement an OR gate (418). In this example, the OR gate (418) outputs a signal indicating a fault when 1) the first D-flop (522-1) indicates a fault, 2) the second D-flop (522-2) indicates a fault, or 3) any upstream zone (104) indicates a fault, wherein a fault is indicated with a logic “1.” If no fault is indicated on any input of the OR gate (418) an output of “O” passes to the next zone (104) and the process repeats.

In this example, the first comparator (110-1) has its “+” terminal connected to the VPP threshold voltage, Vpp threshold, which is provided globally to all zones (104). The“−” terminal of the first comparator (110-1) is connected to the representation of the supply voltage, Vpp.

During operation, the first comparator (110-1) maintains a “0” logic, indicating expected operation, i.e., that the supply voltage, Vpp, at the zone (104) is greater than or equal to the supply voltage threshold, Vpp threshold. In the event that the supply voltage, Vpp, falls below the threshold, Vpp threshold, the output of the first comparator (110-1) will transition from a “0” to a “1” causing the first D-flop (522-1) to clock in a “1” which will then appear on the output “Q” terminal of the first D-flop (522-1). This “1” indicating a supply fault will be communicated to the global die logic, and possibly to the printer, via a communication signal line that combines the fault signals from the D-flops (522) of each zone (104). This “1” will remain on the first D-flop (522-1) until the first D-flop (522-1) is reset. That is, each fault detection device (FIG. 1, 108) includes a reset device, in this example the R terminal and the global reset line, to reset the respective fault capture device (FIG. 1, 112), in this example, the D-flops (522) after the fault has been acknowledged by a controller.

In this example, the second comparator (110-2) has its “−” terminal connected to the Vreturn threshold voltage, Vreturn threshold, which is provided globally to all zones (104). The “+” terminal of the second comparator (110-2) is connected to the return voltage, Vreturn.

During operation, the second comparator (110-2) maintains a “0” logic, indicating expected operation, i.e., that the return voltage, Vreturn, from the zone (104) is less than or equal to the return voltage threshold, Vreturn threshold. In the event that the return voltage, Vreturn, rises above the threshold, Vreturn threshold, the output of the second comparator (110-2) will transition from a “0” to a “1” causing the second D-flop (522-2) to clock in a “1” which will then appear on the output “Q” terminal of the second D-flop (522-2) and output that “1” along the “Q” terminal to be processed at the OR gate (418). This “1” indicating a return fault will be communicated to the global die logic, and possibly to the printer, via a communication signal line that combines the fault signals from the D flops (522) of each zone (104). This “1” will remain on the second D flop (522-2) until the second D-flop (522-2) is reset.

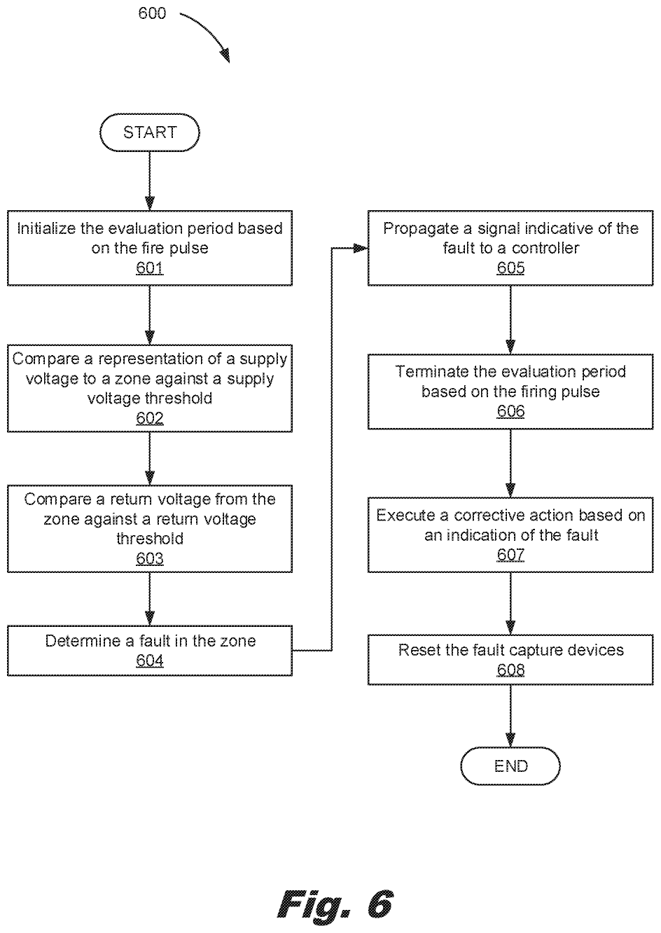

FIG. 6 is a flow chart of a method (600) for zonal actuator evaluation, according to an example of the principles described herein. As described above, the evaluation of fluid actuators (FIG. 1, 106) within a zone (FIG. 1, 104) occurs during an evaluation period. In some examples as described above, the comparators (FIG. 1, 110) are continuously powered. However, in some examples, power conditions are tested just during a predetermined window. The predetermined window may be a “worst case” moment during array firing. That is, to fire fluid actuators (FIG. 1, 106) within an array (FIG. 1, 102), a fire pulse having a predetermined length is passed down the array (FIG. 1, 102). Between subsets of fluid actuators (FIG. 1, 106) in the array (FIG. 1, 102), the fire pulse may be delayed such that not all fluid actuators (FIG. 1, 106) will fire simultaneously and to reduce the rate of change of electrical current in power and return lines. A particular fluid actuator (FIG. 1, 106) fires when it receives the locally-delayed fire pulse and when that actuator's data indicates it is to fire.

In some examples, the fire pulse may provide power such that multiple fluid actuators (FIG. 1, 106) can be fired simultaneously. Depending on the length of the fire pulse, the leading edge of the fire pulse may exit the bottom of the column, i.e., the array (FIG. 1, 102), either before or after the trailing edge of the fire pulse enters the top of the column. More specifically, for a “short” fire pulse, the trailing edge of the fire pulse enters the array (FIG. 1, 102) before the leading edge of the fire pulse exits the array. That is, a short fire pulse may be completely contained within the column at some point in time during its propagation down the column. By comparison, in a “long” fire pulse, the leading edge of the fire pulse exits the array (FIG. 1, 102) before the trailing edge of the fire pulse enters the array. That is, a long fire pulse may fill the entire column at some time during its propagation. As used in the present specification, the fire pulse may be a single pulse or a series of pulses. A “leading edge” refers to the first edge at the beginning of the fire pulse and a “trailing edge” refers to the last edge at the end of the fire pulse.

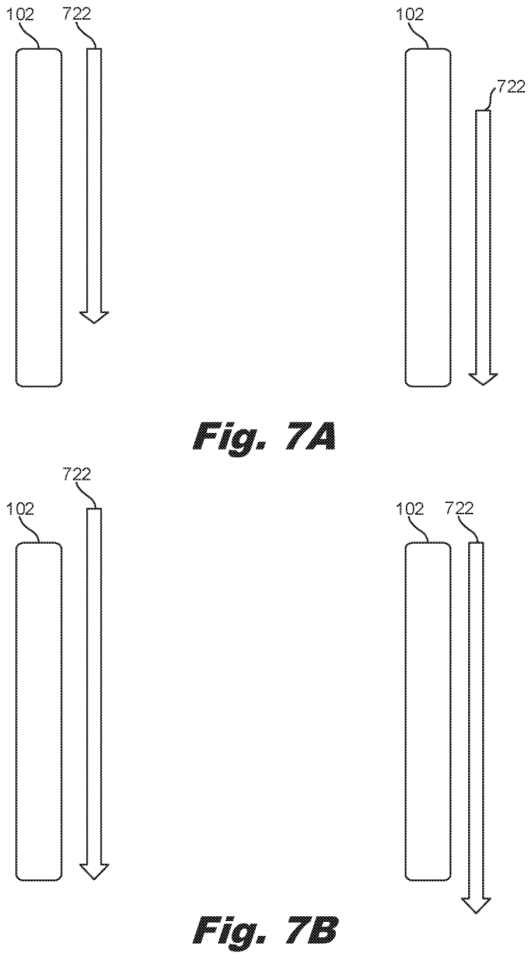

Power delivery system specifications are most likely to be violated, i.e. Vpp drops or Vreturn rises may exceed a threshold, when the maximum number of fluid actuators (FIG. 1, 106) can be simultaneously firing. By comparison, it is not expected that power delivery system specifications would be violated when few or no fluid actuators (FIG. 1, 106) can be firing. Accordingly, the predetermined window, or worst case, may be a time when a maximum number of fluid actuators (FIG. 1, 106) in the array (FIG. 1, 102) are simultaneously actuatable. This period of time when the maximum number of fluid actuators (FIG. 1, 106) are simultaneously actuatable depends on whether a short fire pulse or a long fire pulse is implemented. For a short fire pulse, this period of time is defined from when a trailing edge of the fire pulse hits the first fluid actuator (FIG. 1, 106) in the column to when the leading edge of the fire pulse exits the array (FIG. 1, 102). By comparison, for a long fire pulse, this period of time is defined from when the leading edge of the fire pulse exits the array to when the trailing edge of the fire pulse enters the array FIGS. 7A and 7B below presents a diagrammatic example of these predetermined windows.

Accordingly, in some examples, the comparison of the supply voltage and return voltage at the zone (FIG. 1, 104) against predetermined thresholds can occur during this predetermined window. Accordingly, in one example of the method (600) the evaluation period is initialized (block 601) based on the fire pulse, depending on whether or not the fire pulse is a long fire pulse or a short fire pulse. Such initialization (block 601) can include turning on bias currents to the comparators (FIG. 1, 108), gating error signals before latching a flop, and gating the power signal to the sensing circuits, among others.

Once initialized, the fault detection devices (FIG. 1, 108) are activated. That is, once initialized, the first comparator (FIG. 1, 110-1) compares (block 602) a representation of a supply voltage, Vpp, to a zone (FIG. 1, 104) against a supply voltage threshold, Vpp threshold, and the second comparator (FIG. 1, 110-2) compares (block 603) the return voltage, Vreturn, from a zone (FIG. 1, 104) against a return voltage threshold, Vreturn threshold. Still during the evaluation period, a fault in the zone (FIG. 1, 104) is determined (block 604) and a signal indicative of a fault is propagated (block 605) to the controller. This may be performed as described above in connection with FIG. 3. The evaluation period is then terminated (block 606) based on the fire pulse and whether the fire pulse is a short fire pulse or a long fire pulse.

In some examples, each fault detection device (FIG. 1, 108) is active for a continuous period during the predetermined window. In other examples, each fault detection device (FIG. 1, 108) may be active for a discrete period of time during the predetermined window, which discrete period of time is defined as when a trailing edge of the fire pulse enters the array or when a leading edge of the fire pulse exits the array. Either of these points in time indicates a time when a maximum amount of the fire pulse is in the column such that a maximum number of fluid actuators (FIG. 1, 106) are simultaneously actuatable.

Such a method (600) of performing actuator evaluation during a predetermined, worst case, period of time provides power savings as the fault detection device (FIG. 1, 108) components are not continuously powered but are powered during those times when it is expected that a power fault is likely to occur. Conserving power also increases the life of the die as the fault detection devices (FIG. 1, 108) heat up with power consumption. Heating up creates excess heat in the fluidic die (FIG. 1, 100) which could affect the operation of the components on the die, such as the fluid ejection components. Operating just during a predetermined window also prevents false identification of faults, by limiting an evaluation period to just those times when a power fault is expected.

Corrective actions may then be executed (block 607) based on an indication of the fault. For example, print masks, power settings, print speeds, firing parameters, and other parameters may be adjusted. In one example, the corrective action includes providing a notification to a printer or a user such that manual corrective actions such as maintenance or replacement may occur. Following such corrective action, the fault capture devices (FIG. 1, 112) may be reset (block 608) to no longer indicate a fault.

FIGS. 7A and 7B are diagrams indicating a predetermined window during which actuator evaluation occurs, according to an example of the principles described herein. Specifically, FIG. 7A depicts a predetermined window for a short fire pulse, or when a fire pulse (722) can be completely contained within an array (102) and FIG. 7B depicts a predetermined window for a long fire pulse, or when the fire pulse (722) cannot be completely contained within the array (102).

Turning to FIG. 7A, when the fire pulse (722) is completely contained within the array (102) a maximum number of fluid actuators (FIG. 1, 106) of the array (102) are simultaneously actuatable. It is during this same period of time that a power fault is likely to occur. Accordingly, evaluation occurs during this window, either continuously or at a discrete point in time. Accordingly, the predetermined window starts when the trailing edge of the fire pulse (722) enters the array (102) and terminates when the leading edge of the fire pulse (722) exits the array (102).

Turning to FIG. 7B, when the array (102) is completely addressed by the fire pulse (722) a maximum number of fluid actuators (FIG. 1, 106) of the array (102) are simultaneously actuatable. It is during this same period of time that a power fault is likely to occur. Accordingly, evaluation occurs during this window, either continuously or at a discrete point in time. Accordingly, the predetermined window starts when the leading edge of the fire pulse (722) exits the array (102) and terminates when the trailing edge of the fire pulse (722) enters the array (102).

FIG. 8 is a circuit diagram of a first comparator (110-1) and a second comparator (110-2), according to an example of the principles described herein. As described above, in some examples, the representation of the supply voltage, Vpp, may be a scaled version. This may be because the first comparator (110-1) is a low-voltage comparator and the high voltage that may be provided as the supply voltage, Vpp, may overwhelm the low-voltage first comparator (110-1). Accordingly, the first fault detection device (FIG. 1, 108-1) includes a voltage reducer (824), in this example a voltage divider that enables reduction of the supply voltage, Vpp. Such a voltage reducer (824) may not be present on the second comparator (110-2) as the second comparator (110-2) is comparing a return voltage, Vreturn, with a return voltage threshold, Vreturn threshold, both of which may generally be low voltages.

FIG. 8 also depicts comparison regulators (826-1, 826-2) in the form of transistors. The comparison regulators (826) operate to enable comparison during the predetermined window. In this example, a comparator supply voltage, Vdd, turns the comparators (826) on or off. This signal is allowed to pass via an enable signal, Eval. The enable signal, Eval1, is in the active state during times defined by the predetermined window. Specifically the enable signal, Eval, may be active during the entire predetermined window, or discrete points in time during the predetermined window. Another enable signal, Eval2, may be used to activate the voltage reducer (824) such that the supply voltage is reduced during periods of time when it will be used to determine a fault within the zone (FIG. 1, 104). In some examples, the enable signal for the comparator (110), Eval1, may be delayed relative to the enable signal for the voltage reducer (824), Eval2. This is because it may be desirable for a resistor current to be turned on, and then waiting a period of time for the input to the comparator (110) to stabilize. Following stabilization of the resistor current, the comparator (110) may be enabled via the enable signal for the comparator, Eval1.

In one example, using such a fluidic die 1) allows for immediate detection of power faults at a zone level; 2) reports such faults such that remedial action may be taken; 3) allows for a controller to adjust print masks, power distribution, or other parameters, on the fly to optimize for the actual power delivery limitations of the system; and 4) may leverage circuitry used for other zonal sensing systems such as drive bubble detection systems.

What is claimed is:

1. A fluidic die, comprising:
an array of fluid actuators grouped into zones, each zone comprising:
a number of fluid actuators;
at least one fault detection device comprising:
a comparator to compare at least one of a representation of a supply voltage and a return voltage supplied to the zone against a voltage threshold; and
a fault capture device to store an output of the comparator.

2. The fluidic die of claim 1, wherein:
the at least one fault detection device comprises:
a first fault detection device to compare the representation of the supply voltage against a supply voltage threshold; and
a second fault detection device to compare the return voltage against a return voltage threshold.

3. The fluidic die of claim 1, wherein:
the at least one fault detection device further comprises a comparison regulator to enable comparison during a predetermined window; and
the comparator and fault capture device are continuously active during the predetermined window.

4. The fluidic die of claim 3, wherein the predetermined window comprises a period when a maximum number of actuators in the array are simultaneously actuatable.

5. The fluidic die of claim 1, wherein:
the at least one fault detection device further comprises a comparison regulator to enable comparison during a predetermined window,
wherein the comparator and fault capture device are active when at least one of:
a trailing edge of a fire pulse enters the array; and
a leading edge of the fire pulse exits the array.

6. The fluidic die of claim 1, wherein the at least one fault detection device further comprises a low pass filter disposed on at least one of:
an input of the comparator on which a supply voltage or return voltage is received; and
an output of the comparator.

7. The fluidic die of claim 1, wherein the at least one fault detection device comprises a voltage reducer coupled to an input of the comparator which receives the representation of the supply voltage or the return voltage.

8. The fluidic die of claim 7, wherein the at least one fault detection device further comprises a reducing regulator to enable reduction of the representation of the supply voltage during a predetermined window.

9. The fluidic die of claim 1, wherein the at least one fault detection device further comprises a reset device to reset the fault capture device after the fault has been acknowledged by a controller.

10. A fluidic die, comprising:
an array of fluid actuators grouped into zones, each zone comprising:
a number of fluid actuators;
a first fault detection device comprising:
a first comparator to compare a representation of a supply voltage supplied to the zone against a supply voltage threshold; and
a first fault capture device to store an output of the first comparator;
a second fault detection device comprising:
a second comparator to compare a return voltage from the zone of fluid actuators against a return voltage threshold; and
a second fault capture device to store an output of the second comparator; and
a detection chain to combine outputs of each fault capture device such that the contents of all fault capture devices in the array are conveyed in a collective fashion to a controller.

11. The fluidic die of claim 10, wherein:
each fault capture device is to output a signal indicating a fault based on a fault-indicating output of a respective comparator;
the fault-indicating output of the first comparator indicates the representation of the supply voltage is less than the supply voltage threshold; and
the fault-indicating output of the second comparator indicates the return voltage is greater than the return voltage threshold.

12. The fluidic die of claim 10, wherein the supply voltage threshold and return voltage threshold are passed to all zones in an array of fluid actuators.

13. A method comprising:
during an evaluation mode:
comparing a representation of a supply voltage supplied to a zone of fluid actuators against a supply voltage threshold;
comparing a return voltage from the zone of fluid actuators against a return voltage threshold; and
determining a fault in the zone when at least one of the following conditions exists:
the supply voltage is less than the supply voltage threshold; and
the return voltage is greater than the return voltage threshold; and
propagating a signal indicative of a fault in any of the zones on the fluidic die.

14. The method of claim 13, further comprising:
initializing the evaluation period based on a fire pulse; and
terminating the evaluation period based on the fire pulse.

15. The method of claim 13, further comprising executing a corrective action based on an indication of the fault.
